(19) United States
(12) Patent Application Publication
(10) Pub. No.: US 2025/0273610 A1
(43) Pub. Date: Aug. 28, 2025

(54) SEMICONDUCTOR APPARATUS AND METHOD FOR MANUFACTURING SEMICONDUCTOR APPARATUS

(71) Applicant: Resonac Corporation, Minato-ku, Tokyo (JP)

(72) Inventors: Keiko UENO, Minato-ku, Tokyo (JP); Shizu FUKUZUMI, Minato-ku, Tokyo (JP)

(21) Appl. No.: 18/857,184

(22) PCT Filed: Apr. 22, 2022
(86) PCT No.: PCT/JP2022/018580

§ 371 Date: Oct. 16, 2024

(51) Int. Cl. H01L 23/00; H01L 23/532; H01L 25/065

(52) U.S. Cl. CPC H01L 24/08; H01L 23/5329; H01L 24/16; H01L 24/29; H01L 24/32; H01L 24/73; H01L 24/80; H01L 24/81; H01L 24/94; H01L 25/0657; H01L 2224/08145; H01L 2224/16147; H01L 2224/16227; H01L 2224/16238; H01L 2224/29018; H01L 2224/2919; H01L 2224/29388; H01L 2224/32145; H01L 2224/32225; H01L 2224/73204; H01L 2224/80895; H01L 2224/80896; H01L 2224/81091; H01L 2224/94; H01L 2225/06513; H01L 2225/06517; H01L 2225/06524; H01L 2924/3656

(57) ABSTRACT

A semiconductor device includes a first hybrid bonding structural component and a first bump connection component. The first hybrid bonding structural component includes a first semiconductor component including a first semiconductor chip, and a first insulating layer and a first electrode, and a second semiconductor component including a second semiconductor chip, and a second insulating layer and a second electrode. The first insulating layer and the second insulating layer are bonded to each other, and the first electrode and the second electrode are bonded. The first bump connection component includes a first film member attached to a surface of the second semiconductor chip of the first hybrid bonding structural component, the surface being located on a side opposite to the second insulating layer, and a first connection bump disposed in the first film member and connected to an electrode of the second semiconductor chip.

### TECHNICAL FIELD

The present disclosure relates to a semiconductor device and a method for manufacturing the semiconductor device.

### BACKGROUND ART

Conventionally, a wire bonding method using a metal thin wire such as a gold wire has been widely applied to connect a semiconductor chip to a substrate. On the other hand, a flip chip (FC) connection method of forming a conductive protrusion called a bump on a semiconductor chip or a substrate to directly connect the semiconductor chip to the substrate is becoming widespread to meet a demand for higher functionality, higher integration, higher speed, and the like of a semiconductor device.

As the FC connection method, a method of metal-bonding a connection portion using solder, tin, gold, silver, copper, or the like, a method of metal-bonding a connection portion by applying ultrasonic vibration, a method of maintaining mechanical contact by contraction force of resin, and the like are known. From the viewpoint of reliability of the connection portion, a method of metal-bonding the connection portion using solder, tin, gold, silver, copper, or the like is common.

For example, regarding connection between a semiconductor chip and a substrate, a chip on board (COB) type connection method actively used for a ball grid array (BGA), a chip size package (CSP), and the like also corresponds to the FC connection method. The FC connection method is also widely used in a chip on chip (COG) type connection method in which a connection portion (bump or wiring) is formed on semiconductor chips to connect the semiconductor chips to each other (refer to, for example, Patent Literature 1).

In addition, in packages that are strongly required to be further downsized, thinned, and highly functional, chip stack-type packages, package on package (POP), through-silicon via (TSV), and the like in which the above-described connection methods are used for a stacking step and a multilayer formation step have also started to be widely used. In such a stacking and multilayer-formation technique, the semiconductor chips and the like are three-dimensionally arranged, thereby making it possible to make the package smaller than that using a method of two-dimensionally arranging the semiconductor chips and the like. In addition, such a stacking and multilayer-formation technique is also effective for improving performance of a semiconductor, reducing noise, reducing a mounting area, and saving power, and thus has attracted attention as a next-generation semiconductor wiring technique.

### CITATION LIST

### Patent Literature

Patent Literature 1: Japanese Unexamined Patent Publication No. 2012-222038

### SUMMARY OF INVENTION

### Technical Problem

In a method for manufacturing the semiconductor device having a flip chip package described above, a film-like adhesive is bonded, as an underfill material, to a semiconductor wafer having protruding electrodes in advance, and then the semiconductor wafer having the protruding electrodes is divided into individual semiconductor chips. Then, as illustrated in FIGS. 7A to 7C and FIGS. 8A and 8B, the divided semiconductor chips each having an adhesive are sequentially stacked to obtain a multilayer semiconductor device. However, when the semiconductor chips each having the adhesive are stacked and pressed using a bonding tool, each of the film-like adhesives protrudes outward to form a portion called a fillet 156. When the semiconductor chip is formed as a multilayer type, the fillets 156 adjacent in the stacking direction stick to each other, and a gap V is formed between the fillets 156. When heating and cooling are repeatedly performed for the semiconductor device having such a gap V, the fillets may expand or contract to generate internal stress, and the adhesives or the like may be peeled off starting from the gap V.

An object of the present disclosure is to provide a semiconductor device and a method for manufacturing the semiconductor device capable of improving reliability of the semiconductor device in which semiconductor chips are formed as a multilayer type.

### Solution to Problem

The present disclosure relates to a semiconductor device as one aspect. The semiconductor device includes: a first hybrid bonding structural component including a first semiconductor component and a second semiconductor component, the first semiconductor component including a first semiconductor chip, and a first insulating layer and a first electrode provided on the first semiconductor chip, the second semiconductor component including a second semiconductor chip, and a second insulating layer and a second electrode provided on the second semiconductor chip, the first insulating layer and the second insulating layer being bonded to each other, and the first electrode and the second electrode being bonded to each other; and a first bump connection component including a first adhesive film member attached to a surface of the second semiconductor chip of the first hybrid bonding structural component, the surface being located on a side opposite to the second insulating layer, and a first connection bump disposed in the first adhesive film member and connected to an electrode of the second semiconductor chip.

In the semiconductor device, the semiconductor device is configured to include the first hybrid bonding structural component using a hybrid bonding technique in which the semiconductor chips (or semiconductor wafers or the like) are bonded and connected to each other without using a general adhesive, and the first connection bump having the first adhesive film member. According to such configuration, since the first hybrid bonding structural component can be interposed between the adhesive film members, it is possible to prevent fillets from sticking to each other. Accordingly, formation of a gap in the fillets of the semiconductor device is prevented, and peeling starting from the gap is prevented. As described above, according to the semiconductor device, reliability can be improved. In addition, when the semiconductor chips are connected to each other by the hybrid bonding technique, it is possible to reduce a height of the semiconductor device as compared with connection using a bump or the like, thereby making it possible to reduce the height of the semiconductor device. On the other hand, since the fillet can be formed on the outside of the semiconductor chip using the adhesive film member, it is possible to protect the semiconductor chip in the semiconductor device. As described above, according to the semiconductor device, it is possible to reduce the height of the semiconductor device and improve the protection function thereof.

The semiconductor device may further include: a second hybrid bonding structural component including a third semiconductor component and a fourth semiconductor component, the third semiconductor component including a third semiconductor chip, and a third insulating layer and a third electrode provided on the third semiconductor chip, the fourth semiconductor component including a fourth semiconductor chip, and a fourth insulating layer and a fourth electrode provided on the fourth semiconductor chip, the third insulating layer and the fourth insulating layer being bonded to each other, and the third electrode and the fourth electrode being bonded to each other; and a second bump connection component including a second adhesive film member bonded to a surface of the fourth semiconductor chip of the second hybrid bonding structural component, the surface being located on a side opposite to the fourth insulating layer, and a second connection bump disposed in the second adhesive film member and connected to an electrode of the fourth semiconductor chip. In the semiconductor device, it is preferable that the second adhesive film member of the second bump connection component is bonded to a surface of the first semiconductor chip of the first hybrid bonding structural component, the surface being located on a side opposite to the first insulating layer, and the second connection bump is connected to the electrode of the first semiconductor chip. According to the semiconductor device, reliability of the semiconductor device can be improved even if the semiconductor device is formed as a multilayer type as described above. It is also possible to reduce the height of the semiconductor device and improve the protection function thereof.

The semiconductor device may further include a substrate having a wiring electrode, in which the first connection bump of the first bump connection component may be connected to the wiring electrode. According to such configuration, the first semiconductor component and the substrate can be connected to each other more reliably.

In the semiconductor device, the first adhesive film member may protrude outward from an end portion of the second semiconductor chip to form a fillet. According to such configuration, the semiconductor chip included in the semiconductor device can be more reliably protected. Here, a maximum protruding width of the fillet from the end portion of the second semiconductor chip may be equal to or less than half of a thickness of the first hybrid bonding structural component. According to such configuration, it is possible to provide a more reliable semiconductor device by balancing protection of the semiconductor chip and prevention of peeling.

In the semiconductor device, at least one of the first insulating layer and the second insulating layer may contain an inorganic insulating material. According to such configuration, it is possible to manufacture a semiconductor device having a finer configuration. In addition, since bonding between the inorganic materials is easily strengthened, a bonding strength between the semiconductor chips can be increased, and connection reliability as a semiconductor device can be further improved.

In the semiconductor device, at least one of the first insulating layer and the second insulating layer may contain an organic insulating material. According to such configuration, an organic material, which is a relatively soft material, causes debris generated when the semiconductor chip is diced to be absorbed (incorporated) into an insulating layer portion made of the organic material, thereby making it possible to reduce a connection failure between the semiconductor chips bonded to each other by hybrid bonding.

In the semiconductor device, the organic insulating material included in at least one of the first insulating layer and the second insulating layer may contain polyimide, a polyimide precursor, polyamideimide, benzocyclobutene (BCB), polybenzoxazole (PBO), or a PBO precursor. Since each of the materials is liquid or soluble in a solvent, the first insulating layer and the like can be easily prepared by, for example, spin coating, and a thin film can be easily formed. In addition, each of the materials has high heat resistance, thereby making it possible to withstand a high temperature and the like when bonding is performed by hybrid bonding, and semiconductor chips can be bonded to each other more reliably.

In the semiconductor device, the first adhesive film member may include a cured product of a resin composition containing epoxy resin, thermoplastic resin, a curing agent, and an inorganic filler. According to such configuration, bonding of the first hybrid bonding structural component and the like can be performed more reliably, and reliability of the semiconductor device can be improved.

As another aspect, the present disclosure relates to a method for manufacturing a semiconductor device. A method for manufacturing a semiconductor device includes: preparing a first semiconductor substrate including a first substrate body including a plurality of first semiconductor elements, and a first insulating layer and a plurality of first electrodes provided on the first substrate body; preparing a second semiconductor substrate including a second substrate body including a plurality of second semiconductor elements, and a second insulating layer and a plurality of second electrodes provided on the second substrate body; bonding the first insulating layer of the first semiconductor substrate and the second insulating layer of the second semiconductor substrate to each other and bonding the plurality of first electrodes of the first semiconductor substrate and the plurality of second electrodes of the second semiconductor substrate to obtain a hybrid bonding structure; forming a plurality of connection bumps on a surface of the second substrate body, the surface being opposite to the second insulating layer; bonding an adhesive film member to the surface of the second substrate body, the surface being opposite to the second insulating layer; and dicing the hybrid bonding structure having the adhesive film member bonded thereto to obtain a plurality of hybrid bonding stacked components, each of the hybrid bonding stacked components including at least one first semiconductor element, at least one first electrode, at least one second semiconductor element, at least one second electrode, and at least one connection bump.

In the method for manufacturing the semiconductor device, a hybrid bonding structure is manufactured using a hybrid bonding technique in which semiconductor substrates are bonded and connected to each other without using a general adhesive, and an adhesive film is bonded to the hybrid bonding structure and the hybrid bonding structure is diced into individual pieces, thereby obtaining a hybrid bonding stacked component with an adhesive. According to such manufacturing method, since a portion corresponding to the hybrid bonding structure can be interposed between the adhesive film members, it is possible to prevent fillets from sticking to each other. Accordingly, formation of a gap in the fillets of the semiconductor device is prevented, and peeling starting from the gap is prevented. As described above, according to the method for manufacturing the semiconductor device, reliability of the semiconductor device can be improved. In addition, when the semiconductor chips are connected to each other by the hybrid bonding technique, it is possible to reduce a height of the semiconductor device as compared with connection using a bump or the like, thereby making it possible to manufacture a semiconductor device having a reduced height. On the other hand, since the fillet can be formed on the outside of the semiconductor chip using the adhesive film member, it is possible to obtain the semiconductor device configured to protect the semiconductor chip.

In the method for manufacturing the semiconductor device, the plurality of hybrid bonding stacked components may include a first hybrid bonding stacked component and a second hybrid bonding stacked component, and the method may further include bonding the second hybrid bonding stacked component on a first semiconductor chip corresponding to the first substrate body in the first hybrid bonding stacked component. Then, reliability of the semiconductor device can be improved even if the number of layers is increased. It is also possible to reduce the height of the semiconductor device and improve the protection function thereof.

The method for manufacturing the semiconductor device may further include: pressing the first hybrid bonding stacked component after disposing the first hybrid bonding stacked component on a substrate; and after pressing the first hybrid bonding stacked component, disposing the second hybrid bonding stacked component on the first hybrid bonding stacked component and pressing the second hybrid bonding stacked component. According to such manufacturing method, since each hybrid bonding stacked component is pressed every time the hybrid bonding stacked component is disposed, it is possible to provide a semiconductor device having high connection accuracy by preventing displacement of each hybrid bonding stacked component.

The method for manufacturing the semiconductor device may further include collectively pressing the first hybrid bonding stacked component and the second hybrid bonding stacked component after disposing the second hybrid bonding stacked component on the first hybrid bonding stacked component. According to such method, it is possible to collectively connect the hybrid bonding stacked components, and it is possible to efficiently manufacture the semiconductor device.

In the method for manufacturing the semiconductor device, in any pressing, a portion corresponding to the adhesive film member of at least one stacked component of the first hybrid bonding stacked component and the second hybrid bonding stacked component may be extruded outward from an end portion of the hybrid bonding stacked component in a direction intersecting a pressing direction. According to such manufacturing method, it is possible to manufacture a semiconductor device having a fillet that more reliably protects a semiconductor chip. Here, a maximum extrusion amount by which the portion corresponding to the adhesive film member is extruded outward may be equal to or less than half of a thickness of the hybrid bonding stacked component. According to such manufacturing method, it is possible to provide a more reliable semiconductor device by balancing protection of the semiconductor chip and prevention of peeling.

The method for manufacturing the semiconductor device may further include: preparing a substrate having a wiring electrode provided on a front surface thereof; and mounting the first hybrid bonding stacked component on the substrate to connect the connection bump of the first hybrid bonding stacked component to the wiring electrode. According to such manufacturing method, it is possible to more reliably connect the wiring electrode of the substrate to the connection bump of the first hybrid bonding stacked component.

In the method for manufacturing the semiconductor device, at least one of the first insulating layer of the first semiconductor substrate and the second insulating layer of the second semiconductor substrate may contain an inorganic insulating material. According to such manufacturing method, it is possible to manufacture a semiconductor device having a finer configuration. In addition, since bonding between the inorganic materials is easily strengthened, a bonding strength between the semiconductor chips can be increased, and connection reliability as a semiconductor device can be further improved.

In the method for manufacturing the semiconductor device, at least one of the first insulating layer of the first semiconductor substrate and the second insulating layer of the second semiconductor substrate may contain an organic insulating material. According to such manufacturing method, the organic material, which is a relatively soft material, causes debris generated when the semiconductor substrate is diced into the semiconductor chips to be absorbed (incorporated) in an insulating layer portion made of the organic material, thereby making it is possible to reduce a connection failure between the semiconductor chips bonded to each other by hybrid bonding.

In the method for manufacturing the semiconductor device, the organic insulating material included in at least one of the first insulating layer and the second insulating layer may contain polyimide, a polyimide precursor, polyamideimide, benzocyclobutene (BCB), polybenzoxazole (PBO), or a PBO precursor. Since each of the materials is liquid or soluble in a solvent, the first insulating layer and the like can be easily prepared by, for example, spin coating, and a thin film can be easily formed. In addition, each of the materials has high heat resistance, thereby making it possible to withstand a high temperature and the like when bonding is performed by hybrid bonding, and semiconductor chips can be bonded to each other more reliably.

In the method for manufacturing the semiconductor device, the adhesive film member may contain epoxy resin, thermoplastic resin, a curing agent, and an inorganic filler. According to such manufacturing method, the first hybrid bonding structural component and the like can be bonded more reliably, and reliability of the semiconductor device can be improved.

### Advantageous Effects of Invention

According to the present disclosure, it is possible to provide a semiconductor device having excellent reliability.

### BRIEF DESCRIPTION OF DRAWINGS

FIG. 1 is a cross-sectional view schematically illustrating a semiconductor device according to an embodiment of the present disclosure.

FIG. 2 is a plan view of the semiconductor device illustrated in FIG. 1 as viewed from above.

FIGS. 3A and 3B are cross-sectional views sequentially illustrating a method for manufacturing the semiconductor device illustrated in FIG. 1.

FIGS. 4A and 4B are cross-sectional views sequentially illustrating the method for manufacturing the semiconductor device illustrated in FIG. 1, and are views each illustrating a step following the steps illustrated in FIGS. 3A and 3B.

FIGS. 5A and 5B are cross-sectional views sequentially illustrating the method for manufacturing the semiconductor device illustrated in FIG. 1, and are views each illustrating a step following the steps illustrated in FIGS. 4A and 4B.

FIGS. 6A and 6B are cross-sectional views sequentially illustrating the method for manufacturing the semiconductor device illustrated in FIG. 1, and are views each illustrating a step following the steps illustrated in FIGS. 5A and 5B.

FIGS. 7A to 7C are cross-sectional views sequentially illustrating a method for manufacturing a semiconductor device according to comparison.

FIGS. 8A and 8B are cross-sectional views sequentially illustrating the method for manufacturing the semiconductor device according to the comparative example, and are views each illustrating a step following the steps illustrated in FIGS. 7A to 7C.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description is omitted. Further, unless otherwise specified, a positional relationship such as up, down, left, and right is based on a positional relationship illustrated in the drawings. The use of the terms “left”, “right”, “front”, “back”, “up”, “down”, “above”, “below”, and the like in the description and claims of the specification is intended for description and is not necessarily meant to be a permanent relative position thereof. Furthermore, the dimensional ratios in the drawings are not limited to the illustrated ratios.

In the present specification, the term “layer” includes not only a structure having a shape formed on the entire surface when observed as a plan view, but also a structure having a shape partially formed. In the present specification, the term “step” includes not only an independent step but also a step that cannot be clearly distinguished from other steps as long as an intended action of the step is achieved. In addition, a numerical range indicated using “to” indicates a range including numerical values described before and after “to” as a minimum value and a maximum value, respectively.

### (Configuration of Semiconductor Device)

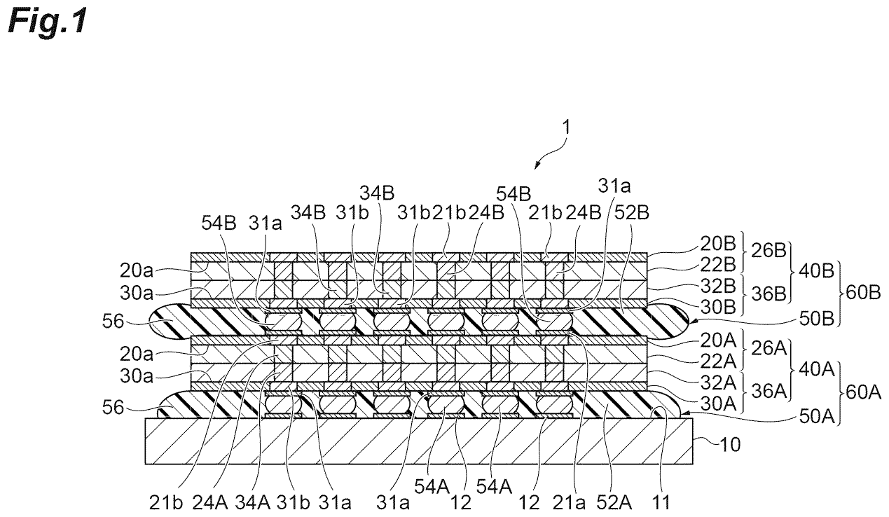

FIG. 1 is a cross-sectional view schematically illustrating an example of a semiconductor device according to the present embodiment. As illustrated in FIG. 1, a semiconductor device 1 is an example of a semiconductor package, for example, and includes a substrate 10, a set of a first hybrid bonding structural component 40A and a first bump connection component 50A disposed on the substrate 10, and another set of a second hybrid bonding structural component 40B and a second bump connection component 50B further disposed on the first hybrid bonding structural component 40A and the first bump connection component 50A. In the semiconductor device 1, the first bump connection component 50A, the first hybrid bonding structural component 40A, the second bump connection component 50B, and the second hybrid bonding structural component 40B are sequentially stacked on the substrate 10. The semiconductor device 1 has fillets 56 respectively formed by causing adhesive film members 52A and 52B of the first bump connection component 50A and the second bump connection component 50B to protrude outward from the end portions thereof. The respective fillets 56 are formed not to stick to each other in a stacking direction.

The substrate 10 has a plurality of wiring electrodes 12 on a front surface 11. The substrate 10 is not particularly limited as long as the substrate 10 is a wiring circuit board, and a circuit board in which wiring (wiring pattern) is formed by removing unnecessary portions by etching from a metal layer formed on the surface of an insulating substrate mainly formed of glass epoxy, polyimide, polyester, ceramic, epoxy, bismaleimide triazine, polyimide, or the like, a circuit board in which wiring (wiring pattern) is formed on the surface of the insulating substrate by metal plating or the like, a circuit board in which wiring (wiring pattern) is formed by printing a conductive substance on the surface of the insulating substrate, or the like can be used. The wiring electrode 12 is configured to include, for example, gold, silver, and/or copper.

A first hybrid bonding stacked component 60A including the first hybrid bonding structural component 40A and the first bump connection component 50A is disposed on the substrate 10. The first hybrid bonding structural component 40A is attached to the substrate 10 by the first bump connection component 50A.

The first hybrid bonding structural component 40A includes a first semiconductor component 26A including a first semiconductor chip 20A, and a first insulating layer 22A and a plurality of first electrodes 24A provided on the first semiconductor chip 20A, and a second semiconductor component 36A including a second semiconductor chip 30A, and a second insulating layer 32A and a plurality of second electrodes 34A provided on the second semiconductor chip 30A. In the first hybrid bonding structural component 40A, the first insulating layer 22A and the second insulating layer 32A are bonded to each other, and the plurality of first electrodes 24A and the plurality of second electrodes 34 are bonded to each other. Various conventional methods can be used for the method of forming the plurality of first electrodes 24A in the first insulating layer 22A and the method of forming the plurality of second electrodes 34A in the second insulating layer 32A, and thus the detailed description thereof is omitted here.

The first semiconductor chip 20A and the second semiconductor chip 30A are not particularly limited, and various semiconductors such as element semiconductors formed of the same type of element such as silicon or germanium, and compound semiconductors such as gallium arsenide or indium phosphide can be used. The first semiconductor chip 20 and the second semiconductor chip 30A may have terminal electrodes 21a and 31a configured to connect the semiconductor chip to the outside, respectively, and through electrodes 21b and 31b penetrating the semiconductor chip, respectively. The terminal electrode 21a of the first semiconductor chip 20A is connected to a terminal electrode 31a of a fourth semiconductor chip 30B via a second connection bump 54B to be described later. The through electrode 21b of the first semiconductor chip 20A is connected to the terminal electrode 21a and the first electrode 24A. The terminal electrode 31a of the second semiconductor chip 30A is connected to the wiring electrode 12 of the substrate 10 via a first connection bump 54A. The through electrode 31b of the second semiconductor chip 30A is connected to the terminal electrode 31a and the second electrode 34A. The thicknesses of the first semiconductor chip 20A and the second semiconductor chip 30A are, for example, in the range of 0.2 mm to 2.0 mm.

The first insulating layer 22A and the second insulating layer 32A are configured to include an inorganic insulating material or an organic insulating material. The first insulating layer 22A and the second insulating layer 32A may be configured to include both an inorganic insulating material and an organic insulating material. The inorganic insulating material used for the insulating layer is, for example, silicon oxide (SiO₂) or the like. When an inorganic insulating material such as silicon oxide is used for the insulating layer, a semiconductor device having a finer configuration can be manufactured. In addition, since bonding between the inorganic insulating materials is easily strengthened, a bonding strength between the semiconductor chips can be increased, and connection reliability as a semiconductor device can be improved.

The organic insulating material used for the first insulating layer 22A and the second insulating layer 32A is, for example, polyimide, a polyimide precursor (for example, polyimide amic ester or polyamic acid), polyamideimide, benzocyclobutene (BCB), polybenzoxazole (PBO), or a PBO precursor. Such organic insulating materials have, for example, a lower elastic modulus than that of inorganic insulating materials such as silicon oxide (SiO₂), and are soft materials. By using such organic insulating materials, when the insulating layers are bonded to each other, even if fine debris is on the insulating layer the debris is absorbed into the insulating layer to prevent a bonding failure due to the debris, and the insulating layers can be reliably bonded to each other. In addition, the elastic modulus of the organic material configuring the first insulating layer 22A and the second insulating layer 32A may be, for example, equal to or less than 7.0 GPa, equal to or less than 5.0 GPa, equal to or less than 3.0 GPa, equal to or less than 2.0 GPa, or equal to or less than 1.5 GPa. The elastic modulus here means Young's modulus. In addition, the organic insulating material configuring the first insulating layer 22A and the second insulating layer 32A preferably has a thermal expansion coefficient equal to or less than 70 ppm/K, and more preferably equal to or less than 50 ppm/K.

The thicknesses of the first insulating layer 22A and the second insulating layer 32A are preferably equal to or less than 10 μm, more preferably equal to or less than 5 μm, and still more preferably equal to or less than 3 μm. By setting the thicknesses of the first insulating layer 22A and the second insulating layer 32A to such thicknesses, the first electrodes 24A and the second electrodes 34A respectively formed in the first insulating layer 22A and the second insulating layer 32A can be miniaturized. The thicknesses of the first insulating layer 22A and the second insulating layer 32A are preferably equal to or more than 1 μm from the viewpoint of securing electrical reliability.

The first electrode 24A and the second electrode 34A are terminal electrodes respectively provided on surfaces 20a and 30a on the inner sides of the first semiconductor chip 20A and the second semiconductor chip 30A, and are made of, for example, copper or aluminum. The first electrode 24A penetrates the first insulating layer 22A and is exposed on a surface of the first insulating layer 22A, in which the surface is disposed on a side opposite to the surface 20a to which the first semiconductor chip 20A is connected. The second electrode 34A penetrates the second insulating layer 32A and is exposed on a surface of the second insulating layer 32A, in which the surface is disposed on a side opposite to the surface 30a to which the second semiconductor chip 30A is connected. In the first hybrid bonding structural component 40A, the first electrode 24A and the second electrode 34A are bonded to each other.

The first bump connection component 50A to which the first hybrid bonding structural component 40A is bonded includes the first adhesive film member 52A bonded to a surface of the second semiconductor chip 30A, in which the surface is disposed on a side opposite to the second insulating layer 32A, and the first connection bump 54A disposed in the first adhesive film member 52A and flip-chip connected to the terminal electrode 31a of the second semiconductor chip 30A. The first connection bump 54A contains, as a main component, gold, silver, copper, solder (the main component is, for example, tin-silver, tin-lead, tin-bismuth, or tin-copper), nickel, tin, lead, or the like, and may contain a plurality of types of metal.

The first adhesive film member 52A includes epoxy resin, thermoplastic resin, a curing agent, a flux agent, and an inorganic filler. The first adhesive film member 52A may be an insulating resin layer containing no conductive filler (conductive particles). In the semiconductor device 1, the first adhesive film member 52A is a cured product of a resin composition containing epoxy resin, thermoplastic resin, a curing agent, a flux agent, and an inorganic filler described above. Such a first adhesive film member 52A can be formed using, for example, a non-conductive film (NCF).

A second hybrid bonding stacked component 60B including the second hybrid bonding structural component 40B and the second bump connection component 50B is disposed on the first hybrid bonding stacked component 60A having such configuration, and the second hybrid bonding structural component 40B is attached to the first semiconductor chip 20A of the first hybrid bonding stacked component 60A by the second bump connection component 50B. The second hybrid bonding stacked component 60B has the same configuration as that of the first hybrid bonding stacked component 60A, and hereinafter, overlapping portions may be partially omitted.

The second hybrid bonding structural component 40B includes a third semiconductor component 26B including a third semiconductor chip 20B, and a third insulating layer 22B and a plurality of third electrodes 24B provided on the third semiconductor chip 20B, and a fourth semiconductor component 36B including the fourth semiconductor chip 30B, and a fourth insulating layer 32B and a plurality of fourth electrodes 34B provided on the fourth semiconductor chip 30B. In the second hybrid bonding structural component 40B, the third insulating layer 22B and the fourth insulating layer 32B are bonded to each other, and the plurality of third electrodes 24B and the plurality of fourth electrodes 34B are bonded to each other.

The third semiconductor chip 20B and the fourth semiconductor chip 30B are semiconductor chips respectively similar to the first semiconductor chip 20A and the second semiconductor chip 30A. The third semiconductor chip 20B and the fourth semiconductor chip 30B may have the terminal electrodes 21a and 31a configured to connect the semiconductor chip to the outside, respectively, and the through electrodes 21b and 31b penetrating the semiconductor chip, respectively. The terminal electrode 31a of the fourth semiconductor chip 30B is connected to the terminal electrode 21a of the first semiconductor chip 20A via the second connection bump 54B. The through electrode 31b of the fourth semiconductor chip 30B is connected to the terminal electrode 31a and the fourth electrode 34B. The thicknesses of the third semiconductor chip 20B and the fourth semiconductor chip 30B are, for example, in the range of 0.2 mm to 2.0 mm, similarly to the first semiconductor chip 20A and the like.

The third insulating layer 22B and the fourth insulating layer 32B are configured to include an inorganic insulating material or an organic insulating material, similarly to the first insulating layer 22A and the second insulating layer 32A. The third insulating layer 22B and the fourth insulating layer 32B may be configured to include both an inorganic insulating material and an organic insulating material. The inorganic insulating material or the organic insulating material used for the insulating layers is the same as that of the first insulating layer 22A. Similarly, the thicknesses of the third insulating layer 22B and the fourth insulating layer 32B are preferably equal to or less than 10 μm, more preferably equal to or less than 5 μm, and still more preferably equal to or less than 3 μm. The thicknesses of the third insulating layer 22B and the fourth insulating layer 32B are preferably equal to or more than 1 μm from the viewpoint of securing electrical reliability.

The third electrode 24B and the fourth electrode 34B are terminal electrodes respectively provided on the surfaces 20a and 30a on the inner sides of the third semiconductor chip 20B and the fourth semiconductor chip 30B, and are made of, for example, copper or aluminum. The third electrode 24B penetrates the third insulating layer 22B and is exposed on a surface of the third insulating layer 22B, in which the surface is disposed on a side opposite to the surface 20a to which the third semiconductor chip 20B is connected. The fourth electrode 34B penetrates the fourth insulating layer 32B and is exposed on a surface of the fourth insulating layer 32B, in which the surface is disposed on a side opposite to the surface 30a to which the fourth semiconductor chip 30B is connected. In the second hybrid bonding structural component 40B, the third electrode 24B and the fourth electrode 34B are bonded to each other.

Similarly to the first bump connection component 50A, the second bump connection component 50B bonded to the second hybrid bonding structural component 40B includes the second adhesive film member 52B bonded to a surface of the fourth semiconductor chip 30B, in which the surface is disposed on a side opposite to the fourth insulating layer 32B, and the second connection bump 54B disposed in the second adhesive film member 52B and flip-chip connected to the terminal electrode 31a of the fourth semiconductor chip 30B. The second connection bump 54B contains, as a main component, gold, silver, copper, solder (the main component is, for example, tin-silver, tin-lead, tin-bismuth, or tin-copper), nickel, tin, lead, or the like, and may contain a plurality of types of metal.

Here, a connection configuration in the semiconductor device 1 having the above-described configuration will be described with reference to FIG. 1 again. In the semiconductor device 1, the first hybrid bonding stacked component 60A in which the first hybrid bonding structural component 40A and the first bump connection component 50A form a pair is disposed on the substrate 10. In the first hybrid bonding stacked component 60A, the wiring electrode 12 of the substrate 10 is connected to the terminal electrode 31a of the second semiconductor chip 30A of the first hybrid bonding structural component 40A via the first connection bump 54A. The terminal electrode 31a is connected to the terminal electrode 21a of the first semiconductor chip 20A via the second electrode 34A, the first electrode 24A, and the through electrode 21b of the first semiconductor chip 20A. The second hybrid bonding stacked component 60B in which the second hybrid bonding structural component 40B and the second bump connection component 50B form a pair is further disposed on the first hybrid bonding stacked component 60A. In the second hybrid bonding stacked component 60B, the terminal electrode 21a of the first semiconductor chip 20A is connected to the terminal electrode 31a of the fourth semiconductor chip 30B of the second hybrid bonding structural component 40B via the second connection bump 54B. The terminal electrode 31a is connected to the through electrode 21b of the third semiconductor chip 20B via the fourth electrode 34B and the third electrode 24B. Note that such a semiconductor device 1 has a configuration in which a hybrid bonding structural component and a bump connection component including an adhesive film member are alternately stacked.

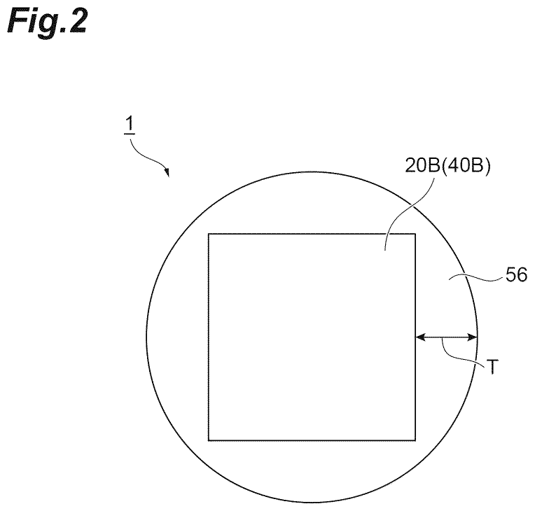

In the semiconductor device 1, the first adhesive film member 52A and the second adhesive film member 52B of the first bump connection component 50A and the second bump connection component 50B protrude outward from the end portions of the respective semiconductor chips, thereby forming the fillets 56. FIG. 2 is a plan view of the semiconductor device 1 as viewed from above. As illustrated in FIG. 2, each fillet 56 is an adhesive portion protruding outward from the entire outer periphery of the semiconductor chip (for example, the third semiconductor chip 20B), and is a portion that can protect the first semiconductor chip 20A, the second semiconductor chip 30A, the third semiconductor chip 20B, and the fourth semiconductor chip 30B in the semiconductor device 1. A maximum value of a protruding width T (a maximum protruding width) of the fillet 56 may be, for example, equal to or less than half of a thickness (height) of the first hybrid bonding structural component 40A or the second hybrid bonding structural component 40B. By providing the fillet 56 having such a width, the fillets 56 adjacent to each other in a vertical direction do not stick to each other, and a function of reliably protecting the semiconductor device 1 can also be achieved.

### (Method for Manufacturing Semiconductor Device)

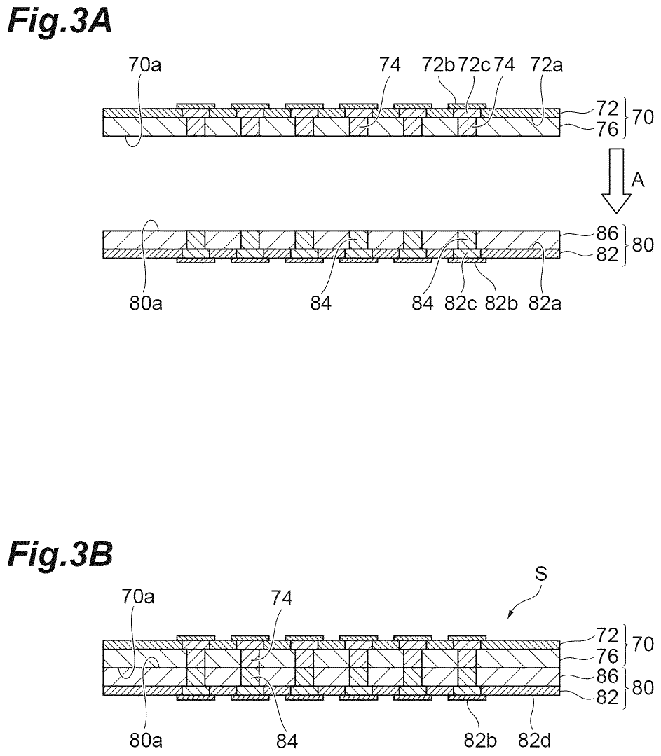

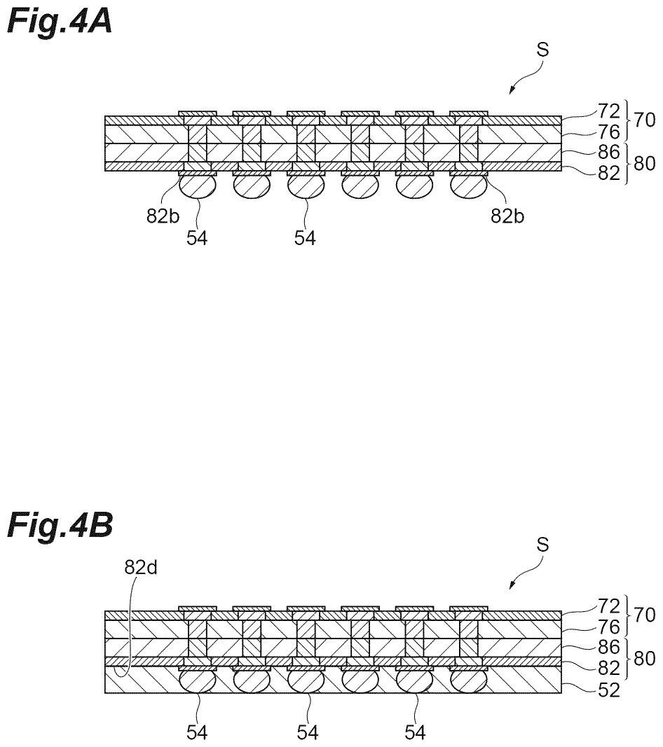

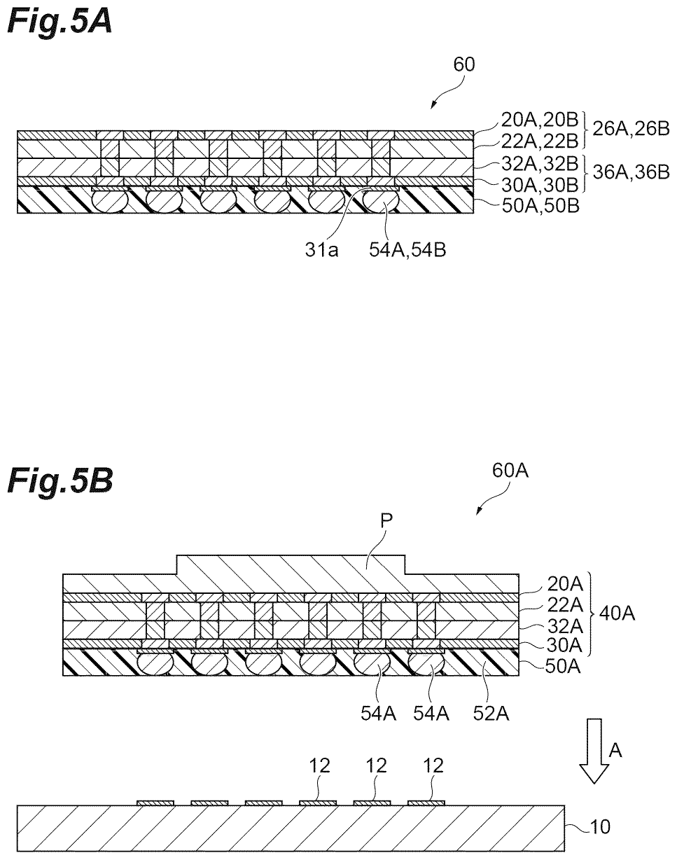

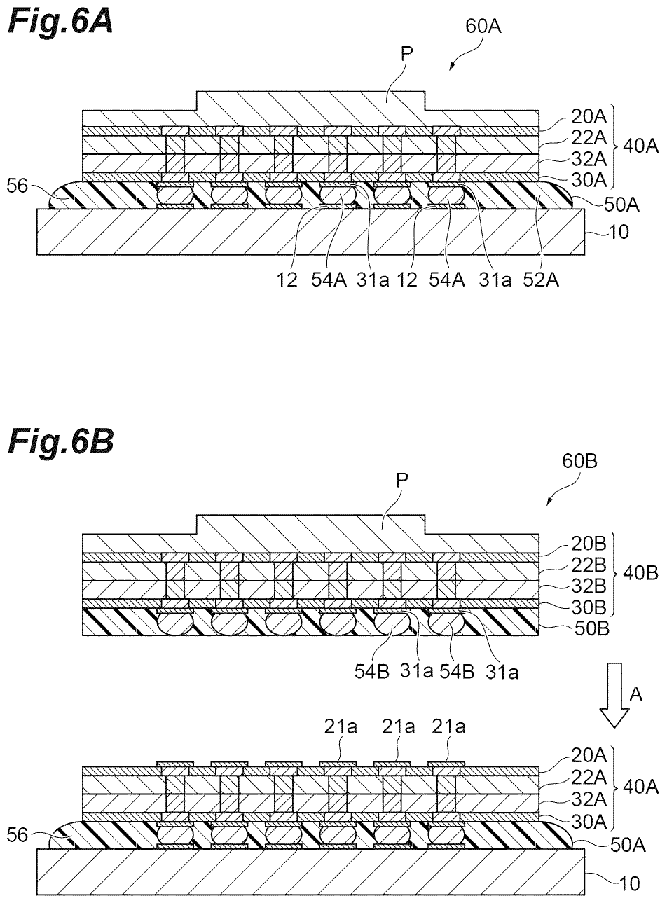

Next, a method for manufacturing the semiconductor device 1 will be described with reference to FIGS. 3A and 3B to FIGS. 5A and 5B. FIGS. 3A and 3B are cross-sectional views sequentially illustrating the method for manufacturing the semiconductor device illustrated in FIG. 1. FIGS. 4A and 4B are cross-sectional views sequentially illustrating the method for manufacturing the semiconductor device illustrated in FIG. 1, and are views each illustrating a step following the steps illustrated in FIGS. 3A and 3B. FIGS. 5A and 5B are cross-sectional views sequentially illustrating the method for manufacturing the semiconductor device illustrated in FIG. 1, and are views each illustrating a step following the steps illustrated in FIGS. 4A and 4B. FIGS. 6A and 6B are cross-sectional views sequentially illustrating the method for manufacturing the semiconductor device illustrated in FIG. 1, and are views each illustrating a step following the steps illustrated in FIGS. 5A and 5B.

The semiconductor device 1 can be manufactured, for example, through the following steps (a) to (h).
(a) A step of preparing a first semiconductor substrate including a first substrate body including a plurality of first semiconductor elements, and a first insulating layer and a plurality of first electrodes provided on the first substrate body.
(b) A step of preparing a second semiconductor substrate including a second substrate body including a plurality of second semiconductor elements, and a second insulating layer and a plurality of second electrodes provided on the second substrate body.
(c) A step of bonding the first insulating layer of the first semiconductor substrate and the second insulating layer of the second semiconductor substrate to each other, and bonding the plurality of first electrodes of the first semiconductor substrate and the plurality of second electrodes of the second semiconductor substrate to each other, thereby obtaining a hybrid bonding structure.
(d) A step of forming a plurality of connection bumps on a surface of the second substrate body, in which the surface is opposite to the second insulating layer.
(e) A step of bonding an adhesive film member to the surface of the second substrate body, in which the surface is opposite to the second insulating layer.
(f) A step of dicing the hybrid bonding structure to which the adhesive film member is bonded to obtain a plurality of hybrid bonding stacked components each including at least one first semiconductor element, at least one first electrode, at least one second semiconductor element, at least one second electrode, and at least one connection bump.
(g) A step of stacking and bonding the plurality of hybrid bonding stacked components to each other.
   [Step (a) and Step (b)]

The step (a) is a step of preparing a first semiconductor substrate 70 which corresponds to a plurality of semiconductor components including the first semiconductor component 26A and the third semiconductor component 26B and is a silicon substrate on which an integrated circuit including semiconductor elements and wirings connecting the semiconductor elements to each other is formed. In the step (a), as illustrated in FIG. 3A, a plurality of first electrodes 74 made of copper, aluminum, or the like are provided at predetermined intervals on one surface 72a of a first substrate body 72 made of silicon or the like, and a first insulating layer 76 made of an inorganic material or an organic material is also provided thereon. The first substrate body 72 may be, for example, a circular or rectangular semiconductor wafer. The first electrode 74 is an end electrode for exposing an integrated circuit or the like formed on the first semiconductor substrate 70 to the outside by penetrating through the first insulating layer 76. The plurality of first electrodes 74 may be provided after the first insulating layer 76 is provided on the one surface 72a of the first substrate body 72, or the first insulating layer 76 may be provided after the plurality of first electrodes 74 are provided on the one surface 72a of the first substrate body 72. The first substrate body 72 may be provided with a terminal electrode 72b connected to the integrated circuit or the like and a through electrode 72c penetrating the substrate body.

The step (b) is a step of preparing a second semiconductor substrate 80 which corresponds to a plurality of semiconductor components including the second semiconductor component 36A and the fourth semiconductor component 36B and is a silicon substrate on which an integrated circuit including semiconductor elements and wirings connecting the semiconductor elements to each other is formed. In the step (b), as illustrated in FIG. 3A, a plurality of second electrodes 84 made of copper, aluminum, or the like are provided at predetermined intervals on one surface 82a of a second substrate body 82 made of silicon or the like, and a second insulating layer 86 made of an inorganic material or an organic material is also provided thereon. Similarly to the first substrate body 72, the second substrate body 82 may be, for example, a circular or rectangular semiconductor wafer. The second electrode 84 is an end electrode for exposing an integrated circuit or the like formed on the second semiconductor substrate 80 to the outside by penetrating through the second insulating layer 86. The plurality of second electrodes 84 may be provided after the second insulating layer 86 is provided on the one surface 82a of the second substrate body 82, or the second insulating layer 86 may be provided after the plurality of second electrodes 84 are provided on the one surface 82a of the second substrate body 82.

The first insulating layer 76 and the second insulating layer 86 used in the step (a) and the step (b) correspond to the first insulating layer 22A, the second insulating layer 32A, the third insulating layer 22B, and the fourth insulating layer 32B described above, and is configured to include an inorganic material or an organic material. The inorganic material used for the insulating layer is, for example, silicon oxide (SiO₂) or the like. When an inorganic material such as silicon oxide is used for the insulating layer, a semiconductor device having a finer configuration can be manufactured. In addition, when the insulating layers are bonded to each other in the step (c) to be described later, bonding between the inorganic materials is easily strengthened, a bonding strength between the semiconductor substrates can be increased, and connection reliability as a semiconductor device can be improved.

The organic material used for the insulating layer is, for example, polyimide, a polyimide precursor (for example, a polyimide amic ester or a polyamic acid), polyamideimide, benzocyclobutene (BCB), polybenzoxazole (PBO), or a PBO precursor. Such organic materials have, for example, a lower elastic modulus than that of inorganic materials such as silicon oxide (SiO₂), and are soft materials. By using such organic materials, when the insulating layers are bonded to each other in the step (c) to be described later, even if fine debris is on the insulating layer, the debris is absorbed into the insulating layer to prevent a bonding failure due to the debris, and the insulating layers can be reliably bonded to each other. In addition, the elastic modulus of the organic material configuring the first insulating layer 76 and the second insulating layer 86 may be, for example, equal to or less than 7.0 GPa, equal to or less than 5.0 GPa, equal to or less than 3.0 GPa, equal to or less than 2.0 GPa, or equal to or less than 1.5 GPa. The elastic modulus here means Young's modulus. In addition, the organic material configuring the first insulating layer 76 and the second insulating layer 86 preferably has a thermal expansion coefficient of equal to or less than 70 ppm/K, and more preferably equal to or less than 50 ppm/K.

In addition, since the organic material used for the insulating layer is liquid or soluble in a solvent, each insulating layer can be easily formed as a thin film by spin coating or the like. Furthermore, since the organic materials have heat resistance, the materials can withstand the temperature (for example, a high temperature equal to or more than 300° C.) at the time of bonding the first electrode 74 and the second electrode 84 in the step (c) to be described later, and bonding between the insulating layers does not deteriorate due to the high temperature. Note that the first insulating layer 76 and the second insulating layer 86 may be insulating layers containing both an inorganic material and an organic material.

The thicknesses of the first insulating layer 76 and the second insulating layer 86 may be equal to or less than 20 μm. By sufficiently reducing the thicknesses of the first insulating layer 76 and the second insulating layer 86, the wiring and the like formed by the first electrode 74 and the second electrode 84 can have a finer configuration. The thicknesses of the first insulating layer 76 and the second insulating layer 86 may be more than 20 μm. Here, when the insulating layers are bonded to each other, more debris can be embedded in the resin insulating layer, and the insulating layers can be bonded to each other more reliably. The thicknesses of the first insulating layer 76 and the second insulating layer 86 may be equal to or more than 4 μm. Here, by embedding minute debris in the resin insulating layer, it is possible to improve connection between the first insulating layer 76 and the second insulating layer 86 even if minute debris remains.

The step (c) is a step of bonding the first insulating layer 76 of the first semiconductor substrate 70 and the second insulating layer 86 of the second semiconductor substrate 80 to each other, and bonding the plurality of first electrodes 74 of the first semiconductor substrate 70 and the plurality of second electrodes 84 of the second semiconductor substrate 80 to each other, thereby obtaining a hybrid bonding structure S. Before the step (c), as pretreatment, a bonding surface 70a of the first semiconductor substrate 70 and a bonding surface 80a of the second semiconductor substrate 80 are polished using a chemical mechanical polishing (CMP) method. For example, the first semiconductor substrate 70 may be polished by the CMP method under the condition of selectively deeply cutting the first electrode 74 made of copper or the like, or may be polished by the CMP method so that each surface of the first electrode 74 coincides with the surface of the first insulating layer 76. The same applies to the polishing of the second semiconductor substrate 80. By such polishing, debris on the surfaces of the first semiconductor substrate 70 and the second semiconductor substrate 80 is also removed.

In the step (c), after an organic substance or a metal oxide adhering to the surfaces of the bonding surface 70a of the first semiconductor substrate 70 and the bonding surface 80a of the second semiconductor substrate 80 is removed, as illustrated in FIGS. 3A and 3B, the bonding surface 70a of the first semiconductor substrate 70 and the bonding surface 80a of the second semiconductor substrate 80 face each other, and the first electrode 74 of the first semiconductor substrate 70 and the second electrode 84 are aligned with each other. In the alignment step, the first insulating layer 76 of the first semiconductor substrate 70 and the second insulating layer 86 of the second semiconductor substrate 80 are spaced from each other and are not bonded to each other. When the alignment is completed, the first insulating layer 76 of the first semiconductor substrate 70 and the second insulating layer 86 of the second semiconductor substrate 80 are bonded to each other. Here, bonding therebetween may be performed after the first insulating layer 76 and the second insulating layer 86 are uniformly heated. The heating temperature at the time of bonding the first insulating layer 76 and the second insulating layer 86 to each other may be, for example, equal to or more than 30° C. and equal to or less than 400° C., and the pressure may be equal to or more than 0.1 MPa and equal to or less than 1 MPa. By thermal bonding at such a temperature, the first insulating layer 76 and the second insulating layer 86 are bonded to each other to form an insulating bonding portion, and the first semiconductor substrate 70 and the second semiconductor substrate 80 are mechanically firmly attached to each other.

When the bonding between the insulating layers is completed, predetermined heat or pressure or both are applied to bond the first electrode 74 of the first semiconductor substrate 70 and the second electrode 84 of the second semiconductor substrate 80 to each other. When the first electrode 74 and the second electrode 84 are made of copper, the heating temperature is equal to or more than 150° C. and equal to or less than 400° C., and may be equal to or more than 200° C. and equal to or less than 300° C., and the pressure may be equal to or more than 0.1 MPa and equal to or less than 1 MPa. By such a bonding process, the first electrode 74 and the second electrode 84 corresponding thereto are bonded to each other to form an electrode bonding portion, and the first electrode 74 and the second electrode 84 are mechanically and electrically firmly bonded to each other. The electrode bonding may be performed after the bonding of the insulating layers, or the electrode bonding and the bonding of the insulating layers may be simultaneously performed. Thus, the hybrid bonding structure S is obtained.

In step (d), a plurality of connection bumps 54 are formed on a surface 82d of the second substrate body 82 of the hybrid bonding structure S, in which the surface 82d is opposite to the second insulating layer 86. The connection bump 54 contains, as a main component, gold, silver, copper, solder (the main component is, for example, tin-silver, tin-lead, tin-bismuth, or tin-copper), nickel, tin, lead, or the like, and may contain a plurality of types of metal. In the step (d), as illustrated in FIG. 4A, such connection bumps 54 are formed to be connected to a plurality of connection terminals 82b of the second substrate body 82. As a manufacturing method, a conventional method can be used.

In the step (e), after the plurality of connection bumps 54 are formed in the step (d), as illustrated in FIG. 4B, an adhesive film member 52 is bonded to the surface 82d of the second substrate body 82, in which the surface 82d is opposite to the second insulating layer 86. By the bonding, the plurality of connection bumps 54 are positioned in the adhesive film member 52. The plurality of connection bumps 54 may or may not be exposed from the surface of the adhesive film member 52.

The adhesive film member 52 used here corresponds to the first adhesive film member 52A and the second adhesive film member 52B described above, and contains epoxy resin, thermoplastic resin, a curing agent, a flux agent, and an inorganic filler. The adhesive film member 52 may be an insulating resin layer containing no conductive filler (conductive particles).

### (Epoxy Resin)

Epoxy resin is not particularly limited as long as the epoxy resin has an epoxy group in the molecule, and epoxy resin having two or more epoxy groups in the molecule can be preferably used. Examples of such epoxy resin include bisphenol A-type epoxy resin, bisphenol F-type epoxy resin, naphthalene-type epoxy resin, phenol novolac-type epoxy resin, cresol novolac-type epoxy resin, phenol aralkyl-type epoxy resin, biphenyl-type epoxy resin, triphenolmethane-type epoxy resin, and dicyclopentadiene-type epoxy resin; and polyfunctional epoxy resins of the above examples. The epoxy resins may be used singly or in combination of two or more kinds thereof. Among the examples, the epoxy resin preferably contains bisphenol-type epoxy resin or triphenolmethane-type epoxy resin.

The epoxy resin is preferably one that can prevent generation of volatile components due to decomposition at the time of connection at a high temperature. Therefore, it is preferable to use epoxy resin having a mass reduction rate equal to or less than 5% by mass under heating conditions at the time of connection. For example, when the heating temperature at the time of connection is 250° C., it is preferable to use epoxy resin having a mass reduction rate equal to or less than 5% by mass at the temperature of 250° C., and when the heating temperature is 300° C., it is preferable to use epoxy resin having a mass reduction rate equal to or less than 5% by mass at the temperature of 300° C.

The content of the epoxy resin is preferably 5 to 75% by mass, more preferably 10 to 55% by mass, and still more preferably 20 to 50% by mass based on the total amount of the adhesive film member. When the content of the epoxy resin is in such a range, curability tends to be more excellent and adhesiveness tends to be more excellent.

### (Thermoplastic Resin)

From the viewpoint of obtaining excellent heat resistance, film formability, and connection reliability, thermoplastic resin preferably contains at least one selected from a group consisting of phenoxy resin, polyimide resin, polyamide resin, polycarbodiimide resin, cyanate ester resin, acrylic resin, polyester resin, polyethylene resin, polyethersulfone resin, polyetherimide resin, polyvinyl acetal resin, urethane resin, and an acrylic rubber. From the viewpoint of further excellent heat resistance and film formability, the thermoplastic resin more preferably contains at least one selected from a group consisting of phenoxy resin, polyimide resin, an acrylic rubber, acrylic resin, cyanate ester resin, and polycarbodiimide resin, and still more preferably contains at least one selected from a group consisting of phenoxy resin, polyimide resin, an acrylic rubber, and acrylic resin.

The weight average molecular weight of the thermoplastic resin is preferably equal to or more than 10,000, more preferably equal to or more than 20,000, and still more preferably equal to or more than 30,000. When the weight average molecular weight of the thermoplastic resin is equal to or more than 10,000, heat resistance and film formability of the adhesive film member tend to be further improved. The weight average molecular weight of the thermoplastic resin is preferably equal to or less than 1,000,000, and more preferably equal to or less than 500,000. When the weight average molecular weight of the thermoplastic resin is equal to or less than 1,000,000, an effect of high heat resistance tends to be obtained.

The weight average molecular weight means a value measured using gel permeation chromatography (GPC) and converted using a calibration curve by standard polystyrene. An example of measurement conditions of the weight average molecular weight is shown below.

Apparatus name: HCL-8320GPC, UV-8320 (manufactured by Tosoh Corporation), or HPLC-8020 (manufactured by Tosoh Corporation)

Column: TSKgel superMultiporeHZ-Mx2, or 2 pieces of GMHXL+1 piece of G-2000XL

Detector: RI or UV detector

Column temperature: 25 to 40° C.

Eluent: a solvent in which an object to be measured is dissolved can be selected. Examples of the solvent include tetrahydrofuran (THF), N,N-dimethylformamide (DMF), N,N-dimethylacetamide (DMA), N-methyl-2 pyrrolidone (NMP), and toluene. When a solvent having polarity is selected, the concentration of phosphoric acid may be adjusted to 0.05 to 0.1 mol/L (usually 0.06 mol/L), and the concentration of LiBr may be adjusted to 0.5 to 1.0 mol/L (usually 0.63 mol/L).

Flow rate: 0.30 to 1.5 mL/min

Standard substance: polystyrene

A mass ratio of the content of the epoxy resin to the content of the thermoplastic resin (content of epoxy resin/content of thermoplastic resin) based on the total amount of the adhesive film member is preferably 0.01 to 20, more preferably 0.05 to 15, and still more preferably 0.1 to 10.

### (Curing Agent)

A curing agent is not particularly limited, and examples thereof include an imidazole-based curing agent, a phenol resin-based curing agent, an acid anhydride-based curing agent, an amine-based curing agent, and a phosphine-based curing agent. Among the examples, the curing agent preferably contains the imidazole-based curing agent from the viewpoint of exhibiting good flux performance and more excellent storage stability and heat resistance of the cured product of the adhesive film.

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, an isocyanuric acid adduct of 2,4-diamino-6-[2′-methylimidazolyl-(1′)]-ethyl-s-triazine, an isocyanuric acid adduct of 2-phenylimidazole, 2-phenyl-4,5-dihydroxymethylimidazole, 2-phenyl-4-methyl-5-hydroxymethylimidazole, and an adduct of epoxy resin and imidazole. The examples may be used singly or in combination of two or more kinds thereof.

Among the examples, from the viewpoint of excellent curability, storage stability, and connection reliability, at least one is preferably selected from a group consisting of an isocyanuric acid adduct of 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, and 2,4-diamino-6-[2′-methylimidazolyl-(1′)]-ethyl-s-triazine, an isocyanuric acid adduct of 2-phenylimidazole, 2-phenyl-4,5-dihydroxymethylimidazole, and 2-phenyl-4-methyl-5-hydroxymethylimidazole. Further, the examples may be microencapsulated and used as a latent curing agent.

The content of the curing agent is preferably 0.1 to 20 parts by mass, and more preferably 0.1 to 10 parts by mass with respect to 100 parts by mass of the epoxy resin. When the content of the curing agent is equal to or more than 0.1 parts by mass with respect to 100 parts by mass of the epoxy resin, curability tends to be further improved, and when the content of the curing agent is equal to or less than 20 parts by mass, the adhesive film is not cured before formation of metal bonding, and a connection failure tends to hardly occur.

### (Flux Agent)

A flux agent can be used without particular limitation as long as the flux agent is a compound having a carboxyl group, and is preferably a dicarboxylic acid (a compound having two carboxyl groups). As compared with a monocarboxylic acid (a compound having one carboxyl group), a dicarboxylic acid tends to be less likely to volatilize even at a high temperature at the time of connection, and tends to be capable of further preventing generation of a void. In addition, when a dicarboxylic acid is used, as compared with a case of using a compound having three or more carboxyl groups, an increase in viscosity of the adhesive film during storage, connection work, and the like can be further prevented, and connectivity of the semiconductor device tends to be further improved.

The flux agent may be, for example, a dicarboxylic acid having a linear or branched alkylene group. Examples of such a dicarboxylic acid include a dicarboxylic acid having a linear alkylene group, such as succinic acid (melting point: 184° C.), glutaric acid (melting point: 95 to 98° C.), adipic acid (melting point: 152° C.), pimelic acid (melting point: 103 to 105° C.), suberic acid (melting point: 141 to 144° C.), azelaic acid (melting point: 109° C.), sebacic acid (melting point: 133 to 137° C.), undecanedioic acid (melting point: 28 to 31° C.), and dodecanedioic acid (melting point: 127 to 129° C.); and a dicarboxylic acid having a branched alkylene group in which one or more hydrogen atoms at the 2- or 3-position of the dicarboxylic acid having a linear alkylene group are substituted with one or more alkyl groups. Examples of the dicarboxylic acid having a branched alkylene group include 2-methylglutaric acid (melting point: 80 to 82° C.). The flux agent preferably contains 2-methylglutaric acid or glutaric acid.

The melting point of the flux agent is preferably equal to or less than 150° C., more preferably equal to or less than 140° C., and still more preferably equal to or less than 130° C. Such a flux agent tends to easily exhibit sufficient flux performance before a curing reaction between the epoxy resin and the curing agent occurs. Therefore, by using an adhesive film containing such a flux agent, a semiconductor device further excellent in connection reliability can be manufactured. The flux agent is preferably solid at room temperature (25° C.), and a melting point of the flux agent is preferably equal to or more than 25° C., and more preferably equal to or more than 50° C.

The content of the flux agent may be, for example, 0.5 to 10% by mass based on the total amount of the adhesive film.

### (Inorganic Filler)

When the adhesive film member contains an inorganic filler, there is a tendency that generation of voids is further prevented at the time of connection, and hygroscopicity of a cured product of the adhesive film can be further reduced.

The inorganic filler is preferably an insulating substance from the viewpoint of excellent insulation reliability (particularly, HAST resistance). Examples of such inorganic filler include glass, silica, alumina, titanium oxide, carbon black, mica, and boron nitride. The examples may be used singly or in combination of two or more kinds thereof. Among the examples, the inorganic filler is preferably at least one selected from a group consisting of silica, alumina, titanium oxide, and boron nitride, and more preferably at least one selected from a group consisting of silica, alumina, and boron nitride. Shapes and particle sizes of the examples are not particularly limited. The inorganic filler may be subjected to surface treatment.

The content of the inorganic filler is preferably 20 to 70% by mass, more preferably 25 to 65% by mass, and still more preferably 30 to 60% by mass based on the total amount of the adhesive film member. When the content of the inorganic filler is in such a range, the appearance of the adhesive film tends to be smooth, and dispersion of each component tends to be facilitated.

### (Resin Filler)

The adhesive film may further contain a resin filler. Examples of the resin filler include a filler made of resin such as polyurethane and polyimide. The content of the resin filler is preferably 1 to 30% by mass, more preferably 2 to 30% by mass, and still more preferably 3 to 15% by mass based on the total amount of the adhesive film.

### (Other Components)

The adhesive film member may further contain, as other components, a curing accelerator, a silane coupling agent, a titanium coupling agent, an antioxidant, a leveling agent, an ion trapping agent, and the like. The content of the other components can be appropriately adjusted so that each component exhibits a respective effect, and may be, for example, 0.1 to 20% by mass with respect to the total amount of the adhesive film.

The adhesive film member can be formed, for example, by the following method. First, an organic solvent is added as necessary to a resin composition containing each of the above-described components configuring the adhesive film, and a resin composition varnish obtained by stirring and mixing, kneading, or the like is applied onto a release-treated base film using a knife coater, a roll coater, an applicator, or the like. Thereafter, the applied resin composition varnish is heated to remove the organic solvent, whereby the adhesive film can be formed on the base film.

The organic solvent used for preparing the resin composition varnish is not particularly limited as long as the organic solvent has a property of uniformly dissolving or dispersing each component, and examples thereof include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. The organic solvents can be used singly or in combination of two or more kinds thereof. Among the examples, the organic solvent preferably contains methyl ethyl ketone.

Stirring and mixing, kneading, and the like in the preparation of the resin composition varnish can be performed using, for example, a stirrer, a Raikai machine, a three-roll mill, a ball mill, a bead mill, a homodisper, or the like.

The base film is not particularly limited as long as the base film has heat resistance capable of withstanding heating conditions when the organic solvent is dried. Examples of the base film include polyolefin films such as polypropylene films and polymethylpentene films, polyester films such as polyethylene terephthalate films and polyethylene naphthalate films, polyimide films, and polyetherimide films. The base film may be a single monolayer film or a multilayer film obtained by combining two or more kinds.

The thickness of the resulting adhesive film can be adjusted, for example, based on the height of the bump before connection, and is preferably 0.5 to 1.5 times, more preferably 0.6 to 1.3 times, and still more preferably 0.7 to 1.2 times, based on the height of the bump before connection. When the thickness of the adhesive film is equal to or more than 0.5 times the height of the bump, generation of voids due to the adhesive film not being filled can be sufficiently preventing, and connection reliability can be further improved. In addition, when the thickness of the adhesive film is equal to or less than 1.5 times, the amount of the adhesive film extruded from a chip connection region at the time of connection can be sufficiently reduced, and further, adhesion of the adhesive film to an unnecessary portion can be sufficiently prevented. Therefore, it is not necessary to remove the adhesive film from the bump, a conduction failure can be prevented, and damage can be reduced against weakening of the bump (miniaturization of a bump diameter) due to narrowed pitch and increased number of pins. Since the height of the bump is generally 5 to 100 μm, the thickness of the adhesive film is preferably 2.5 to 150 μm and more preferably 3.5 to 120 μm.

A drying condition for volatilizing the organic solvent from the resin composition varnish applied to the base film is not particularly limited as long as the organic solvent is sufficiently volatilized, but heating at 50 to 200° C. for 0.1 to 90 minutes is preferable. The organic solvent is preferably removed to be equal to or less than 1.5% by mass with respect to the total amount of the adhesive film.

In the step (f), the hybrid bonding structure S to which the adhesive film member 52 made of the above-described material is bonded is diced to obtain a plurality of hybrid bonding stacked components 60 each including at least one first semiconductor element, at least one first electrode 74, at least one second semiconductor element, at least one second electrode 84, and at least one connection bump 54. Upon completion of the step (e), the hybrid bonding structure S to which the adhesive film member 52 is bonded is diced using plasma dicing, stealth dicing, laser dicing, or the like to be divided into individual pieces. As a result, as illustrated in FIG. 5A, the individual hybrid bonding stacked component 60 is obtained. The hybrid bonding stacked component 60 corresponds to the first hybrid bonding stacked component 60A and the second hybrid bonding stacked component 60B described above.

In the step (g), the plurality of individualized hybrid bonding stacked components 60 are stacked and bonded to each other. In the step (g), first, as illustrated in FIG. 5B, the first hybrid bonding stacked component 60A is picked up by a bonding tool P and is moved toward the substrate 10. Thereafter, the first hybrid bonding stacked component 60A is disposed on the substrate 10, and then the first hybrid bonding stacked component 60A is pressed while being heated. Here, as illustrated in FIG. 6A, each of the first connection bumps 54A is connected to the corresponding wiring electrode 12. In other words, the terminal electrode 31a of the second semiconductor chip 30A is connected to the wiring electrode 12 via the first connection bump 54A. During the pressing, the first adhesive film member 52A protrudes outward from the end portion of the second semiconductor chip 30A, thereby forming the fillet 56. A protruding width of the fillet 56 is similar to the protruding width T described above.

Subsequently, as illustrated in FIG. 6B, the second hybrid bonding stacked component 60B is picked up by the bonding tool P, the second hybrid bonding stacked component 60B is disposed on the first hybrid bonding stacked component 60A, and the second hybrid bonding stacked component 60B is pressed. Here, the terminal electrode 31a of the fourth semiconductor chip 30B is connected to the terminal electrode 21a of the first semiconductor chip 20A via the second connection bump 54B. In addition, the second bump connection component 50B is bonded to the first semiconductor chip 20A. As described above, the semiconductor device 1 illustrated in FIG. 1 can be obtained.

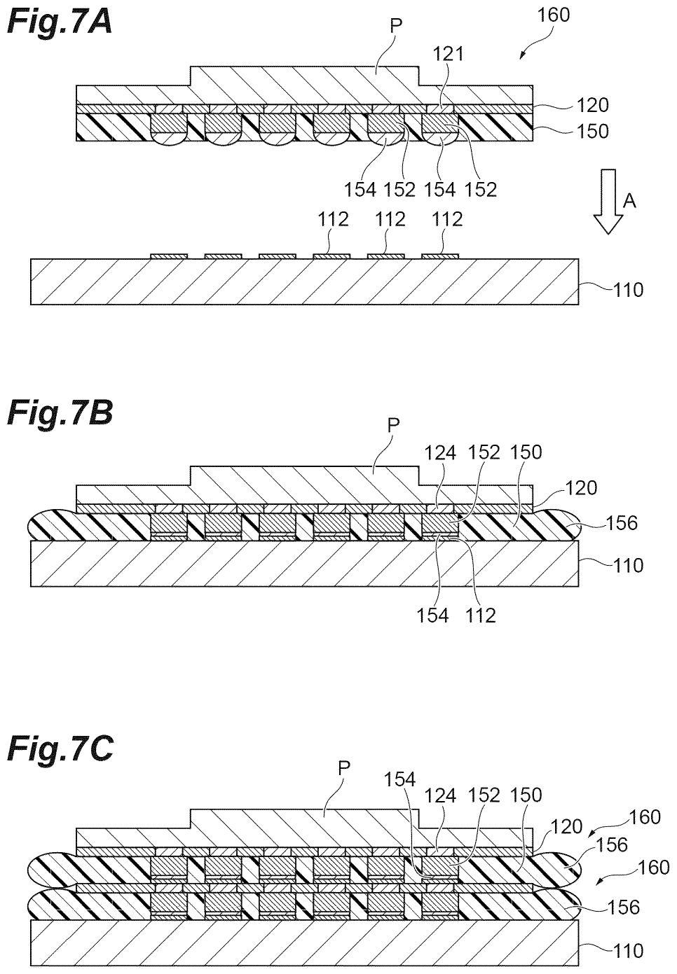

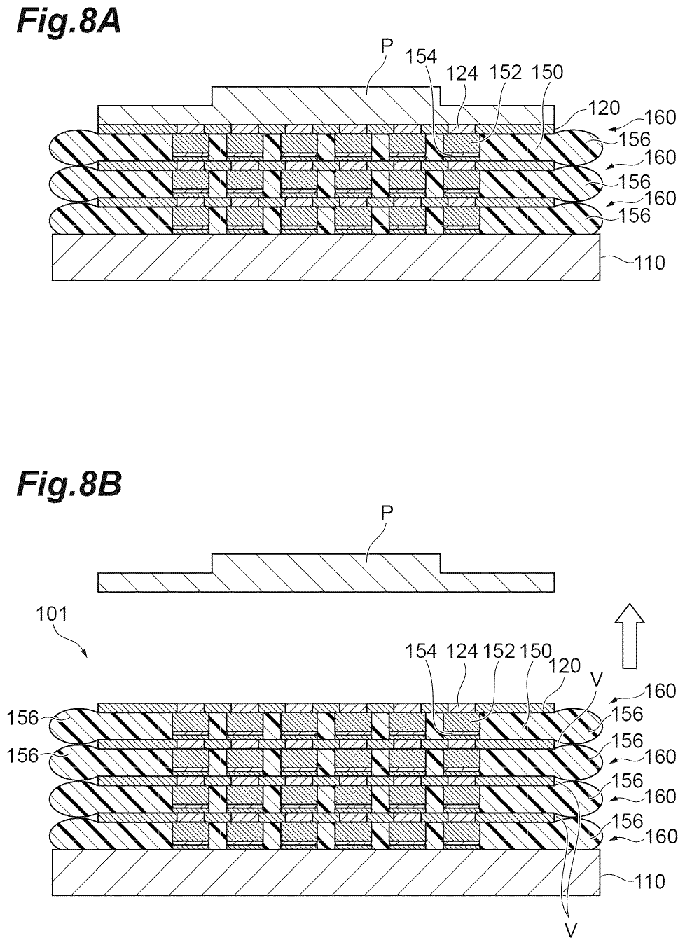

Here, functions and effects of the semiconductor device 1 and the method for manufacturing the semiconductor device 1 according to the present embodiment will be described in comparison with a semiconductor device 101 of a comparative example and a method for manufacturing the semiconductor device 101. FIGS. 7A to 7C and FIGS. 8A and 8B are views each illustrating the semiconductor device according to the comparative example and the method for manufacturing the semiconductor device. As illustrated in FIG. 7A, connection bumps 152 and 154 are provided on the lower surface of a semiconductor chip 120, and a member 160 in which an adhesive film member 150 is attached to the semiconductor chip 120 to cover the connection bumps 152 and 154 is prepared. The adhesive film member 150 corresponds to the adhesive film member 50 and the like. Such a member is picked up by a bonding tool P and is moved toward a substrate 110 to connect the connection bumps 152 and 154 to a connection terminal 112, as illustrated in FIG. 7B. By the connection, an end portion of the adhesive film member 150 protrudes outward to form a fillet 156.

Subsequently, as illustrated in FIGS. 7C, 8A, and 8B, such members 160 are stacked to manufacture the semiconductor device 101. Here, when each of the members 160 is pressed against and attached to a corresponding one of the lower members 160, the fillet 156 is formed, and the fillets 156 adjacent to each other in a stacking direction stick to each other. Accordingly, a gap V which is a closed space is formed between the fillets 156. When heating and cooling are repeatedly performed for the semiconductor device 101 having such a gap V, the fillets 156 may expand or contract to generate internal stress, and the adhesive or the like may be peeled off starting from the gap V.

On the other hand, in the semiconductor device 1 according to the embodiment, the semiconductor device 1 is configured to include the first hybrid bonding structural component 40A using a hybrid bonding technique in which semiconductor chips (or semiconductor wafers or the like) are bonded and connected to each other without using a general adhesive, and the first bump connection component 50A having the first adhesive film member 52A. According to such configuration, since the first hybrid bonding structural component 40A can be interposed (sandwiched) between the adhesive film members, it is possible to prevent the fillets 56 from sticking to each other. Accordingly, formation of a gap in the fillet 56 of the semiconductor device is prevented, and peeling starting from the gap is prevented. As described above, according to the semiconductor device 1, reliability of the apparatus can be improved. In addition, when the semiconductor chips are connected to each other by the hybrid bonding technique, it is possible to reduce a height of the semiconductor device 1 as compared with connection using a bump or the like, and thus, it is possible to reduce the height of the semiconductor device 1. On the other hand, since the fillet 56 can be formed on the outside of the semiconductor chip using the adhesive film member 52, it is possible to protect the semiconductor chip in the semiconductor device 1. As described above, according to the semiconductor device 1, it is possible to reduce the height of the semiconductor device 1 and improve the protection function thereof.

The semiconductor device 1 further includes the substrate 10 having the wiring electrode 12, in which the first connection bump 54A of the first bump connection component 50A is connected to the wiring electrode 12. According to such configuration, the first semiconductor component and the substrate can be connected to each other more reliably.

In the semiconductor device 1, the first adhesive film member 52A protrudes outward from the end portion of the second semiconductor chip 30A to form the fillet 56. According to such configuration, the semiconductor chip included in the semiconductor device 1 can be more reliably protected. Here, the maximum protruding width of the fillet 56 from the end portion of the second semiconductor chip 30A is preferably equal to or less than half of the thickness of the first hybrid bonding structural component 40A. According to such configuration, it is possible to provide a more reliable semiconductor device by balancing protection of the semiconductor chip and prevention of peeling.

In the semiconductor device 1, at least one of the first insulating layer 22A and the second insulating layer 32A may contain an inorganic insulating material. According to such configuration, it is possible to manufacture a semiconductor device having a finer configuration. In addition, since bonding between the inorganic materials is easily strengthened, a bonding strength between the semiconductor chips can be increased, and connection reliability as a semiconductor device can be further improved.

In the semiconductor device 1, at least one of the first insulating layer 22A and the second insulating layer 32A may contain an organic insulating material. According to such configuration, an organic material, which is a relatively soft material, causes debris generated when the semiconductor chip is diced to be absorbed (incorporated) into an insulating layer portion made of the organic material, thereby making it possible to reduce a connection failure between the semiconductor chips bonded to each other by hybrid bonding.

In the semiconductor device 1, the organic insulating material included in at least one of the first insulating layer 22A and the second insulating layer 32A may include polyimide, a polyimide precursor, polyamideimide, benzocyclobutene (BCB), polybenzoxazole (PBO), or a PBO precursor. Since each of the materials is liquid or soluble in a solvent, the first insulating layer and the like can be easily prepared by, for example, spin coating, and a thin film can be easily formed. In addition, each of the materials has high heat resistance, thereby making it possible to withstand a high temperature and the like when bonding is performed by hybrid bonding, and semiconductor chips can be bonded to each other more reliably.

In the semiconductor device 1, the first adhesive film member 52A preferably includes a cured product of a resin composition containing epoxy resin, thermoplastic resin, a curing agent, and an inorganic filler. According to such configuration, bonding of the first hybrid bonding structural component 40A and the like can be performed more reliably, and reliability of the semiconductor device can be improved.

Although embodiments of the present invention have been described in detail above, the present invention is not limited to the embodiments. For example, in the embodiments, description has been given as to an example in which two sets of hybrid bonding stacked components 60 are stacked, but the present invention is not limited thereto. Three or more sets of hybrid bonding stacked components 60 may be stacked to form a semiconductor device.

### REFERENCE SIGNS LIST

1 SEMICONDUCTOR DEVICE
10 SUBSTRATE
12 WIRING ELECTRODE
20A FIRST SEMICONDUCTOR CHIP
20B THIRD SEMICONDUCTOR CHIP
21a TERMINAL ELECTRODE
21b THROUGH ELECTRODE
22A FIRST INSULATING LAYER
22B THIRD INSULATING LAYER
24A FIRST ELECTRODE
24B THIRD ELECTRODE
26A FIRST SEMICONDUCTOR COMPONENT
26B THIRD SEMICONDUCTOR COMPONENT
30A SECOND SEMICONDUCTOR CHIP
30B FOURTH SEMICONDUCTOR CHIP
31a TERMINAL ELECTRODE
31b THROUGH ELECTRODE
32A SECOND INSULATING LAYER
32B FOURTH INSULATING LAYER
34A SECOND ELECTRODE
34B FOURTH ELECTRODE
36A SECOND SEMICONDUCTOR COMPONENT
36B FOURTH SEMICONDUCTOR COMPONENT
40A FIRST HYBRID BONDING STRUCTURAL COMPONENT
40B SECOND HYBRID BONDING STRUCTURAL COMPONENT
50A FIRST BUMP CONNECTION COMPONENT
50B SECOND BUMP CONNECTION COMPONENT
52A FIRST ADHESIVE FILM MEMBER
52B SECOND ADHESIVE FILM MEMBER
54A FIRST CONNECTION BUMP
54B SECOND CONNECTION BUMP
56 FILLET
60 HYBRID BONDING STACKED COMPONENT
60A FIRST HYBRID BONDING STACKED COMPONENT
60B SECOND HYBRID BONDING STACKED COMPONENT
S HYBRID BONDING STRUCTURE
T PROTRUDING WIDTH (MAXIMUM PROTRUDING WIDTH)
V GAP

1. A semiconductor device comprising:
a first hybrid bonding structural component including a first semiconductor component and a second semiconductor component, the first semiconductor component including a first semiconductor chip, and a first insulating layer and a first electrode provided on the first semiconductor chip, the second semiconductor component including a second semiconductor chip, and a second insulating layer and a second electrode provided on the second semiconductor chip, the first insulating layer and the second insulating layer being bonded to each other, and the first electrode and the second electrode being bonded to each other; and
a first bump connection component including a first adhesive film member attached to a surface of the second semiconductor chip of the first hybrid bonding structural component, the surface being located on a side opposite to the second insulating layer, and a first connection bump disposed in the first adhesive film member and connected to an electrode of the second semiconductor chip.

2. The semiconductor device according to claim 1, further comprising:
a second hybrid bonding structural component including a third semiconductor component and a fourth semiconductor component, the third semiconductor component including a third semiconductor chip, and a third insulating layer and a third electrode provided on the third semiconductor chip, the fourth semiconductor component including a fourth semiconductor chip, and a fourth insulating layer and a fourth electrode provided on the fourth semiconductor chip, the third insulating layer and the fourth insulating layer being bonded to each other, and the third electrode and the fourth electrode being bonded to each other; and
a second bump connection component including a second adhesive film member bonded to a surface of the fourth semiconductor chip of the second hybrid bonding structural component, the surface being located on a side opposite to the fourth insulating layer, and a second connection bump disposed in the second adhesive film member and connected to an electrode of the fourth semiconductor chip,
wherein the second adhesive film member of the second bump connection component is bonded to a surface of the first semiconductor chip of the first hybrid bonding structural component, the surface being located on a side opposite to the first insulating layer, and the second connection bump is connected to an electrode of the first semiconductor chip.

3. The semiconductor device according to claim 1, further comprising:
a substrate having a wiring electrode,
wherein the first connection bump of the first bump connection component is connected to the wiring electrode.

4. The semiconductor device according to claim 1,
wherein the first adhesive film member protrudes outward from an end portion of the second semiconductor chip to form a fillet.

5. The semiconductor device according to claim 4,
wherein a maximum protruding width of the fillet from the end portion of the second semiconductor chip is equal to or less than half of a thickness of the first hybrid bonding structural component.

6. The semiconductor device according to claim 1,
wherein at least one of the first insulating layer and the second insulating layer includes an inorganic insulating material.

7. The semiconductor device according to claim 1,
wherein at least one of the first insulating layer and the second insulating layer includes an organic insulating material.

8. The semiconductor device according to claim 7,
wherein the organic insulating material included in at least one of the first insulating layer and the second insulating layer includes polyimide, a polyimide precursor, polyamideimide, benzocyclobutene (BCB), polybenzoxazole (PBO), or a PBO precursor.

9. The semiconductor device according to claim 1,
wherein the first adhesive film member includes a cured product of a resin composition containing epoxy resin, thermoplastic resin, a curing agent, and an inorganic filler.

10. A method for manufacturing a semiconductor device, the method comprising:
preparing a first semiconductor substrate including a first substrate body including a plurality of first semiconductor elements, and a first insulating layer and a plurality of first electrodes provided on the first substrate body;
preparing a second semiconductor substrate including a second substrate body including a plurality of second semiconductor elements, and a second insulating layer and a plurality of second electrodes provided on the second substrate body;
bonding the first insulating layer of the first semiconductor substrate and the second insulating layer of the second semiconductor substrate to each other and bonding the plurality of first electrodes of the first semiconductor substrate and the plurality of second electrodes of the second semiconductor substrate to obtain a hybrid bonding structure;
forming a plurality of connection bumps on a surface of the second substrate body, the surface being opposite to the second insulating layer;
bonding an adhesive film member to the surface of the second substrate body, the surface being opposite to the second insulating layer; and
dicing the hybrid bonding structure having the adhesive film member bonded thereto to obtain a plurality of hybrid bonding stacked components, each of the hybrid bonding stacked components including at least one first semiconductor element, at least one first electrode, at least one second semiconductor element, at least one second electrode, and at least one connection bump.

11. The method for manufacturing a semiconductor device according to claim 10,
wherein the plurality of hybrid bonding stacked components include a first hybrid bonding stacked component and a second hybrid bonding stacked component, the method further comprising
bonding the second hybrid bonding stacked component on a first semiconductor chip corresponding to the first substrate body in the first hybrid bonding stacked component.

12. The method for manufacturing a semiconductor device according to claim 11, further comprising:
pressing the first hybrid bonding stacked component after disposing the first hybrid bonding stacked component on a substrate; and
after pressing the first hybrid bonding stacked component, disposing the second hybrid bonding stacked component on the first hybrid bonding stacked component and pressing the second hybrid bonding stacked component.

13. The method for manufacturing a semiconductor device according to claim 11, further comprising
collectively pressing the first hybrid bonding stacked component and the second hybrid bonding stacked component after disposing the second hybrid bonding stacked component on the first hybrid bonding stacked component.

14. The method for manufacturing a semiconductor device according to claim 12,
wherein, in the pressing, a portion corresponding to the adhesive film member of at least one stacked component of the first hybrid bonding stacked component and the second hybrid bonding stacked component is extruded outward from an end portion of the hybrid bonding stacked component in a direction intersecting a pressing direction.

15. The method for manufacturing a semiconductor device according to claim 14,
wherein a maximum extrusion amount by which the portion corresponding to the adhesive film member is extruded outward is equal to or less than half of a thickness of a portion corresponding to the hybrid bonding structure in the hybrid bonding stacked component.

16. The method for manufacturing a semiconductor device according to claim 11, further comprising:
preparing a substrate having a wiring electrode provided on a front surface thereof, and
mounting the first hybrid bonding stacked component on the substrate to connect the connection bump of the first hybrid bonding stacked component to the wiring electrode.

17. The method for manufacturing a semiconductor device according to claim 10,
wherein at least one of the first insulating layer of the first semiconductor substrate and the second insulating layer of the second semiconductor substrate contains an inorganic insulating material.

18. The method for manufacturing a semiconductor device according to claim 10,
wherein at least one of the first insulating layer of the first semiconductor substrate and the second insulating layer of the second semiconductor substrate contains an organic insulating material.

19. The method for manufacturing a semiconductor device according to claim 18,
wherein the organic insulating material included in at least one of the first insulating layer and the second insulating layer contains polyimide, a polyimide precursor, polyamideimide, benzocyclobutene (BCB), polybenzoxazole (PBO), or a PBO precursor.

20. The method for manufacturing a semiconductor device according to claim 10,
wherein the adhesive film member contains epoxy resin, thermoplastic resin, a curing agent, and an inorganic filler.
